(19) United States
(12) Patent Application Publication
(10) Pub. No.: US 2017/0060425 A1
(43) Pub. Date: Mar. 2, 2017

(54) MEMORY SYSTEM AND METHOD OF CONTROLLING NONVOLATILE MEMORY

(71) Applicant: Kabushiki Kaisha Toshiba, Minato-ku (JP)

(72) Inventors: Tetsuya SUNATA, Kawasaki (JP); Daisuke IWAI, Yokohama (JP); Keigo HARA, Kamakura (JP); Masanobu SHIRAKAWA, Chigasaki (JP)

(73) Assignee: Kabushiki Kaisha Toshiba, Minato-ku (JP)

(21) Appl. No.: 15/062,849

(22) Filed: Mar. 7, 2016

Related U.S. Application Data
(60) Provisional application No. 62/210,754, filed on Aug. 27, 2015.

(51) Int. Cl. G06F 3/06; G11C 16/26; G11C 16/10

(52) U.S. Cl. CPC G06F 3/064; G06F 3/0616; G06F 3/0679; G11C 16/10; G11C 16/26

(57) ABSTRACT

According to one embodiment, a controller writes first data requested to be written from a host into a third block among a plurality of first blocks in a case where a temperature of a nonvolatile memory is within a certain range. In a case where the temperature of the nonvolatile memory is out of the certain range, the controller determines a degree of wear of the third block and writes the first data into a second block in a case where the degree of wear of the third block is more than a threshold.

### CROSS-REFERENCE TO RELATED APPLICATIONS

This application is based upon and claims the benefit of priority from U.S. Provisional Application No. 62/210,754, filed on Aug. 27, 2015; the entire contents of which are incorporated herein by reference.

### FIELD

Embodiments described herein relate generally to a memory system including a nonvolatile memory and a method of controlling a nonvolatile memory.

### BACKGROUND

In a storage device including a semiconductor memory such as a NAND flash memory, in order to cope with a temperature change, various control processes are executed.

### BRIEF DESCRIPTION OF THE DRAWINGS

FIG. 1 is a functional block diagram that illustrates the internal configuration of a memory system according to a first embodiment;

FIG. 2 is a diagram that illustrates an example of the configuration of a block of a memory cell array having a two-dimensional structure;

FIG. 3 is a diagram that illustrates an example of the configuration of a block of a memory cell array having a three-dimensional structure;

FIG. 4 is a cross-sectional view of a partial area of a memory cell array of a NAND memory having a three-dimensional structure;

FIG. 5 is a diagram that illustrates a degree of wear management table;

FIG. 6 is a diagram that illustrates a table managing valid data of a saving block;

FIG. 7 is a flowchart that illustrates an example of the operation of a memory system according to a first embodiment at the time of receiving a write command;

FIG. 8 is a flowchart that illustrates an example of a data moving process of a saving block;

FIG. 9 is a flowchart that illustrates another example of a data moving process of a saving block;

FIG. 10 is a flowchart that illustrates further another example of a data moving process of a saving block;

FIG. 11 is a functional block diagram that illustrates the internal configuration of a memory system according to a second embodiment;

FIG. 12 is a diagram that illustrates a temperature coefficient management table;

FIG. 13 is a diagram that illustrates an example of the internal configuration of a memory chip; and

FIG. 14 is a flowchart that illustrates an example of the operation of the memory system according to the second embodiment.

### DETAILED DESCRIPTION

In general, according to one embodiment, a memory system includes a nonvolatile memory and a controller. The nonvolatile memory includes a plurality of blocks. The plurality of blocks includes a plurality of first blocks and at least one second block. Each second block includes a plurality of memory cells capable of storing data of one bit. In a case where a first temperature that is a temperature of the nonvolatile memory is within a certain range, the controller writes first data requested to be written from a host into one of the first blocks. In a case where the first temperature is out of the certain range, the controller determines a first value of a third block. the third block is a block selected from among the first blocks. the first value is a degree of wear. In a case where the first value of the third block is more than a threshold, the controller writes the first data into the second block. In a case where the first value of the third block is less than the threshold, the controller writes the first data into the third block.

Exemplary embodiments of memory system and a method of controlling a nonvolatile memory will be explained below in detail with reference to the accompanying drawings. The present invention is not limited to the following embodiments.

### First Embodiment

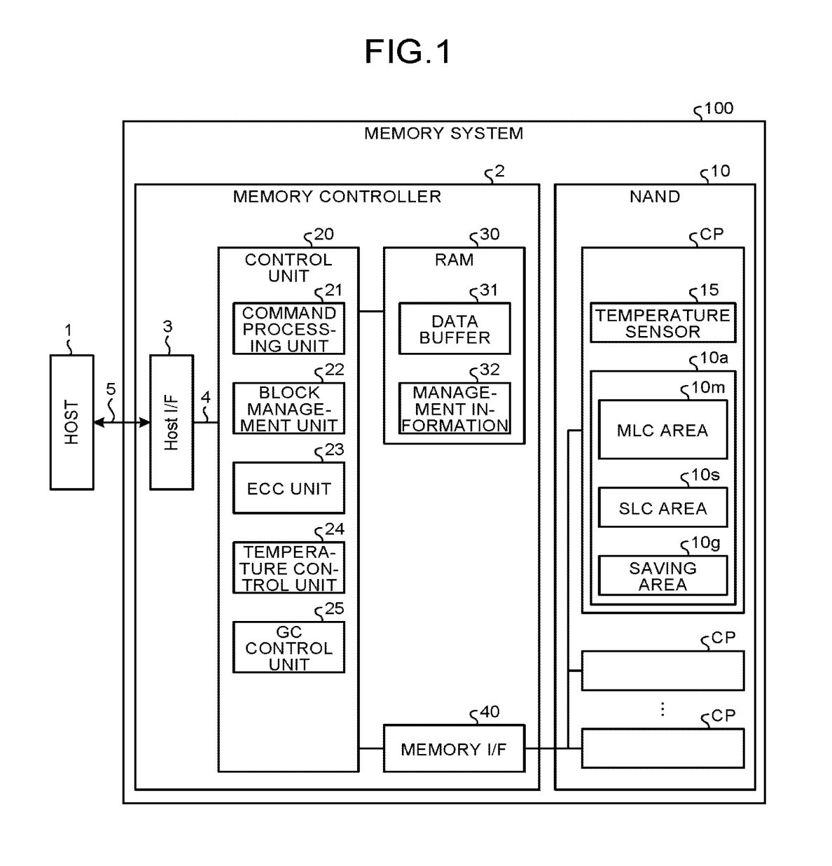

FIG. 1 is a block diagram that illustrates an example of the configuration of a memory system 100 according to a first embodiment. The memory system 100 is connected to a host apparatus (hereinafter, abbreviated as a host) through a communication line 5 and functions as an external storage device of the host 1. The host 1, for example, may be an information processing apparatus such as a personal computer, a mobile phone, or an imaging apparatus, may be a mobile terminal such as a tablet computer or a smart phone, a gaming device, or an in-vehicle terminal such as a car navigation system.

The memory system 100 includes: a NAND flash memory (hereinafter, abbreviated as a NAND) 10 as a nonvolatile memory; and a memory controller 2. The nonvolatile memory device is not limited to the NAND flash memory but may be a flash memory having a three-dimensional structure, a resistance random access memory (ReRAM), a ferroelectric random access memory (FeRAM), or the like.

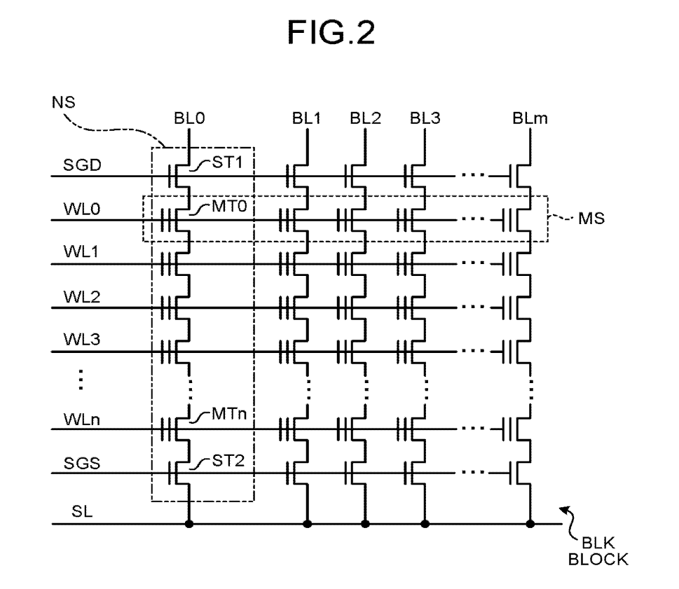

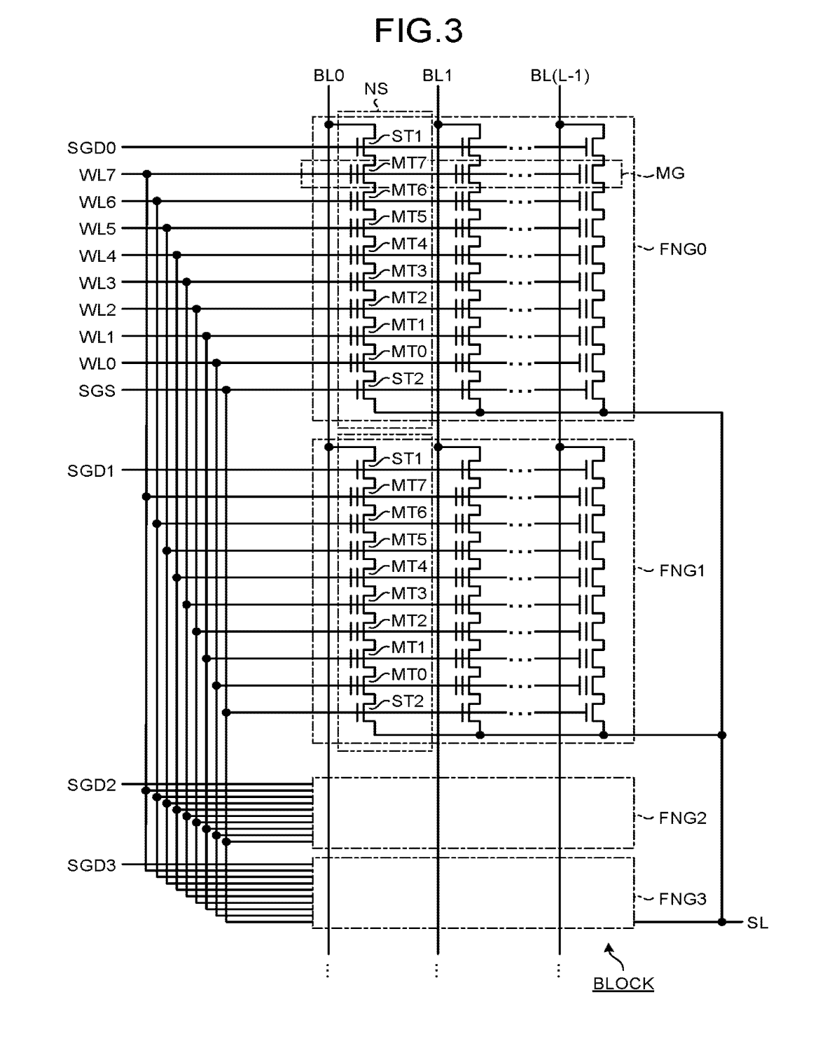

The NAND 10 includes one or more memory chips cp each including a memory cell array. The memory cell array includes a plurality of memory cells arranged in a matrix pattern. The memory cell array includes a plurality of blocks that are units for data erasing. Each block is configured by a plurality of physical sectors MS (see FIG. 2) and MG (see FIG. 3).

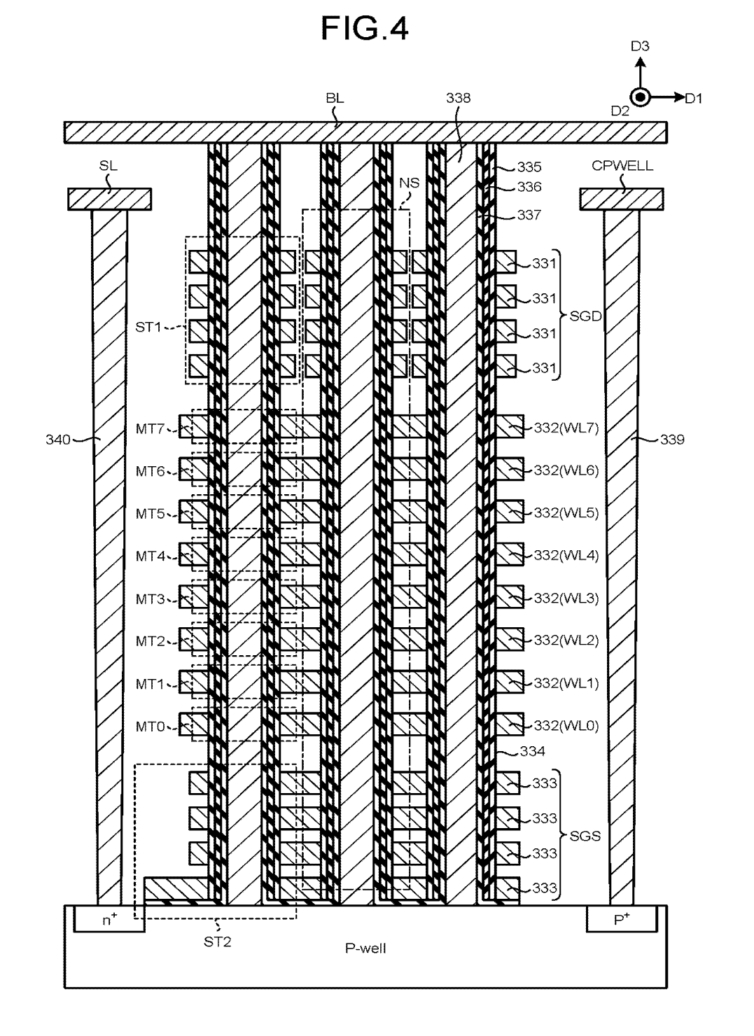

The memory cell array that is the premise of this embodiment is not particularly limited to a specific configuration but may be a memory cell array having a two-dimensional structure as illustrated in FIG. 2 or a memory cell array having a three-dimensional structure as illustrated in FIGS. 3 and 4 or may employ any other configuration.

FIG. 2 is a diagram that illustrates an example of the configuration of a block of the memory cell array having a two-dimensional structure. FIG. 2 illustrates one of a plurality of blocks that configure the memory cell array having the two-dimensional structure. The other blocks of the memory cell array have the same configuration as that illustrated in FIG. 2. As illustrated in FIG. 2, the block BLK of the memory cell array includes (m+1) (here, m is an integer of 0 or more) NAND strings NS. Each NAND string NS shares a diffusion region (a source region or a drain region) between memory cell transistors MT adjacent to each other. Each NAND string NS includes: (n+1) (here, n is an integer of zero or more) memory cell transistors MT0 to MTn connected in series; and selection transistors ST1 and ST2 arranged at both ends of the column of the (n+1) memory cell transistors MT0 to MTn.

Word lines WL0 to WLn are respectively connected to control gate electrodes of the memory cell transistors MT0 to MTn that configure the NAND string NS, and, memory cell transistors MTi (here, i=0 to n) included in each NAND string NS are connected to be common using the same word line WLi (here, i=0 to n). In other words, the control gate electrodes of the memory cell transistors MTi disposed in the same row within the block BLK are connected to the same word line WLi.

Each of the memory cell transistors MT0 to MTn is configured by a field effect transistor having a stacked gate structure formed on a semiconductor substrate. Here, the stacked gate structure includes: a charge storage layer (floating gate electrode) formed on the semiconductor substrate with a gate insulating film being interposed therebetween; and a control gate electrode formed on the charge storage layer with an inter-gate insulating film being interposed therebetween. A threshold voltage of each of the memory cell transistors MT0 to MTn changes according to the number of electrons that is stored in the floating gate electrode and thus, can store data according to a difference in the threshold voltage.

Bit lines BL0 to BLm are respectively connected to the drains of (m+1) selection transistors ST1 within one block BLK, and a selection gate line SGD is connected to be common to the gates of the selection transistors. In addition, the source of the selection transistor ST1 is connected to the drain of the memory cell transistor MT0. Similarly, a source line SL is connected to be common to the sources of the (m+1) selection transistors ST2 within one block BLK, and a selection gate line SGS is connected to be common to the gates of the selection transistors. In addition, the drain of the selection transistor ST2 is connected to the source of the memory cell transistor MTn.

Each memory cell is connected not only to the word line but also to the bit line. Each memory cell can be identified by using an address used for identifying a word line and an address used for identifying a bit line. As described above, the data of the memory cells (the memory cell transistors MT) disposed within the same block BLK is erased altogether. On the other hand, data is written and read in units of physical sectors MS. One physical sector MS includes a plurality of memory cells connected to one word line.

Each memory cell can perform multi-value storage. In a case where the memory cells are operated in a single level cell (SLC) mode, one physical sector MS corresponds to one page. On the other hand, in a case where the memory cells are operated in a multiple level cell (MLC) mode, one physical sector MS corresponds to N pages (here, N is a natural number of two or more). In descriptions presented here, the term MLC mode is assumed to include a triple level cell (TLC) mode of N=3.

In a read operation and a program operation, one word line is selected according to the physical address, and one physical sector MS is selected. A switching of the page within this physical sector MS is performed using the physical address.

FIG. 3 is a diagram that illustrates an example of the configuration of a block of a memory cell array having a three-dimensional structure. FIG. 3 illustrates one block BLK among a plurality of blocks configuring the memory cell array having the three-dimensional structure. Another block of the memory cell array has a configuration similar to that illustrated in FIG. 3.

As illustrated in the figure, the block BLK, for example, includes four fingers FNG (FNG0 to FNG3). In addition, each finger FNG includes a plurality of NAND strings NS. Each NAND string NS, for example, includes eight memory cell transistors MT (MT0 to MT7) and selection transistors ST1 and ST2. Here, the number of memory cell transistors MT is not limited to eight. The memory cell transistor MT is arranged between the selection transistors ST1 and ST2 such that the current paths thereof are connected in series. The current path of the memory cell transistor MT7 disposed on one end side of the series connection is connected to one end of the current path of the selection transistor ST1, and the current path of the memory cell transistor MT0 disposed on the other end side is connected to one end of the current path of the selection transistor ST2.

The gates of the selection transistors ST1 of the fingers FNG0 to FNG3 are commonly connected respectively to selection gate lines SGD0 to SGD3. On the other hand, the gates of the selection transistors ST2 are commonly connected to the same selection gate line SGS among a plurality of fingers FNG. In addition, the control gates of the memory cell transistors MT0 to MT7 disposed inside a same block BLK0 are commonly connected to word lines WL0 to WL7. In other words, while the word lines WL0 to WL7 and the selection gate lines SGS are commonly connected among the plurality of fingers FNG0 to FNG3 disposed inside a same block BLK, the selection gate line SGD is independent for each of the fingers FNG0 to FNG3 also inside the same block BLK.

The word lines WL0 to WL7 are connected to the control gate electrodes of the memory cell transistors MT0 to MT7 configuring the NAND string NS, and the memory cell transistors MTi (i=0 to n) of each NAND string NS are commonly connected by a same word line WLi (i=0 to n). In other words, the control gate electrodes of the memory cell transistors MTi disposed in the same row disposed inside the block BLK are connected to a same word line WLi.

Each memory cell is connected to a word line and a bit line. Each memory cell can be identified by using an address used for identifying a word line and an address used for identifying a bit line. As described above, data of memory cells (memory cell transistors MT) disposed inside a same block BLK is erased together. On the other hand, data reading and data writing are executed in units of physical sectors MG. One physical sector MG includes a plurality of memory cells that are connected to one word line WL and belong to one finger FNG.

Each memory cell can store a multi-value. In a case where a memory cell is operated in a single level cell (SLC) mode, one physical sector MG corresponds to one page. On the other hand, in a case where a memory cell is operated in a multi-level cell (MLC) mode, one physical sector MG corresponds to N pages (here, N is a natural number of two or more). In description here, the term MLC mode is assumed to include a triple level cell (TLC) mode in which N=3.

When a read operation or a program operation is executed, one word line is selected according to a physical address, whereby a plurality of physical sectors MG are selected. A switching of the page within these physical sectors MG is performed using the physical address.

FIG. 4 is a cross-sectional view of a partial area of a memory cell array of a NAND memory having a three-dimensional structure. As illustrated in FIG. 4, a plurality of NAND strings NS are formed on a P-well region. In other words, on the P-well region, a plurality of wiring layers 333 serving as selection gate lines SGS, a plurality of wiring layers 332 serving as word lines WL, and a plurality of wiring layers 331 serving as select gate lines SGD are formed.

A memory hole 334 that arrives at the P-well region through such wiring layers 333, 332, and 331 is formed. On the side face of the memory hole 334, a block insulating film 335, an electric charge accumulating layer 336, and a gate insulating film 337 are sequentially formed, and a conductive film 338 is embedded inside the memory hole 334. The conductive film 338 functions as a current path of the NAND string NS and is an area in which a channel is formed when the memory cell transistors MT and the selection transistors ST1 and ST2 operate.

In each NAND string NS, the selection transistor ST2, a plurality of the memory cell transistors MT, and the selection transistor ST1 are sequentially stacked on the P-well region. At the upper end of the conductive film 338, a wiring layer serving as a bit line BL is formed.

In addition, an n+ type impurity diffusion layer and a p+ type impurity diffusion layer are formed inside the front face of the P-well region. A contact plug 340 is formed on the n+ type impurity diffusion layer, and a wiring layer serving as a source line SL is formed on the contact plug 340. In addition, a contact plug 339 is formed on the p+ type impurity diffusion layer, and a wiring layer serving as a well wiring CPWELL is formed on the contact plug 339.

A plurality of the configurations illustrated in FIG. 4 are arranged in a depth direction of the paper face of FIG. 4, and one finger FNG is formed by a set of a plurality of NAND strings aligned in one line in the depth direction.

In the configuration illustrated in FIG. 1, in the NAND 10, user data transmitted from the host 1, management information of the memory system 100, firmware (not illustrated in the drawing), and the like are stored. The firmware operates a CPU (not illustrated in the drawing) that realizes at least a part of the function of a control unit 20 of the memory controller 2. The firmware may be stored in a ROM not illustrated in the drawing. The management information includes a logical/physical translation table, a block management table, and the like.

Each chip cp includes a temperature sensor 15. The temperature sensor 15 measures the temperature of the memory cell array disposed in each chip. Temperature information TC measured by the temperature sensor 15 is output to the memory controller 2 and is used for temperature control that is executed by the memory controller 2.

In each chip cp, a user data area 10a in which user data is stored includes an MLC area 10m, an SLC area 10s, and a saving area 10g. The MLC area 10m includes a plurality of MLC blocks. The MLC block is a block that operates in the MLC mode. The SLC area 10s includes one or a plurality of SLC blocks. The SLC block is a block that operates in the SLC mode. The SLC area 10s functions as an internal data buffer of the NAND 10. Random write data among write data specified by a write request from the host 1 is stored in the SLC area 10s. In a case where the SLC area 10s is full of data, the data of the SLC area 10s is moved to the MLC area 10m. On the other hand, sequential write data among write data specified by a write request from the host 1 is stored in the MLC area 10m.

The saving area 10g includes one or a plurality of SLC blocks. When the inside of the chip is at an abnormal temperature, write data specified by a write request from the host 1 is written into a block (saving block) disposed inside the saving area 10g. A condition for the use of the saving area 10g will be described below in detail. The saving area 10g is used only when the inside of the chip is at an abnormal temperature. That is, the saving area 10g includes one or a plurality of dedicated blocks that are only used as a writing destination at the time of a temperature abnormality. For this reason, a block disposed inside the saving area 10g has a fewer number of times of rewriting than a block disposed inside the SLC area 10s or the MLC area 10m and a degree of wear smaller than that of a block disposed inside the SLC area 10s or the MLC area 10m. In description presented here, a large degree of wear corresponds to the progress of wear, and a small degree of wear corresponds to no progress of wear.

The memory controller 2 includes: a host interface 3; a memory interface 40; a RAM 30; and the control unit 20. In this embodiment, while the RAM 30 is provided inside the memory controller 2, the RAM 30 may be provided outside the memory controller 2. The host I/F 3 outputs a command, user data (write data), and the like received from the host 1 to an internal bus 4. In addition, the host I/F 3 transmits the user data read from the NAND 10, a response from the control unit 20, and the like to the host 1. The memory I/F 40 directly controls the NAND 10 based on an instruction from the control unit 20.

The RAM 30 is a volatile semiconductor memory that can be accessed at a higher speed than the NAND 10. The RAM 30 includes a storage area as a data buffer 31. Data received from the host 1 is temporarily stored in the data buffer 31 before being written into the NAND 10. Data read from the NAND 10 is temporarily stored in the data buffer 31 before being transmitted to the host 1. The management information stored in the NAND 10 is loaded into the RAM 30. Management information 32 loaded into the RAM 30 is backed up into the NAND 10. The RAM 30 also functions as a buffer in which the firmware stored in the NAND 10 is loaded. As the RAM 30, a static random access memory (SRAM) or a dynamic random access memory (DRAM) is used.

The control unit 20 includes: a command processing unit 21; a block management unit 22, an ECC unit 23; a temperature control unit 24; and a garbage collection (GC) control unit 25. The function of the control unit 20 is realized by one or a plurality of CPUs (processors) executing firmware loaded in the RAM 20 and peripheral circuits thereof. The function of the command processing unit 21 is realized by a CPU and/or hardware that executes firmware. The function of the block management unit 22 is realized by a CPU and/or hardware that execute firmware. The function of the ECC unit 23 is realized by a CPU and/or hardware that execute firmware. The function of the temperature control unit 24 is realized by a CPU and/or hardware that execute firmware. The function of the garbage collection (GC) control unit 25 is realized by a CPU and/or hardware that execute firmware.

The command processing unit 21 executes a process corresponding to a command received from the host 1. For example, in a case where a write request is received from the host 1, the command processing unit 21 temporarily stores write data in the data buffer 31. When the data buffer 31 is full, for example, the command processing unit 21 reads data stored in the data buffer and writes the read data into the NAND 10 through the ECC unit 23 and the memory I/F 40.

On the other hand, in a case where a read request is received from the host 1, the command processing unit 21 instructs the memory I/F 40 to read data from the NAND 10. The memory I/F 40 temporarily stores the data read from the NAND 10 in the data buffer 31 through the ECC unit 23. The command processing unit 21 transmits the read data stored in the data buffer 31 to the host 1 through the host I/F 3.

The command processing unit 21 manages the user data by using a logical/physical translation table that is included in the management information 32 that is loaded into the RAM 30. In the logical/physical translation table, mapping associating a logical address used by the host 1 with the physical address of the RAM 20 or the NAND 10 is registered. As the physical address, for example, logical block addressing (LBA) is used. The physical address represents a storage position on the RAM 20 or the NAND 10 at which the data is stored.

The block management unit 22 executes the management of blocks included in the NAND 10 by using the block management table that is included in the management information 32 loaded in the RAM 30. In the block management table, for example, the following block management information is managed.

The number of times of erasing (Erase Count) in units of blocks

Information representing whether a block is an active block or a free block

Block address of a bad block

An active block is a block in which valid data is recorded. A free block is a block in which valid data has not been recorded and is reusable after erasing the data. The valid data is data associated with a logical address, and invalid data is data not associated with a logical address. When data is written into a free block after erasing data stored therein, the free block becomes an active block. A bad block is an unusable block that does not normally operate due to various factors.

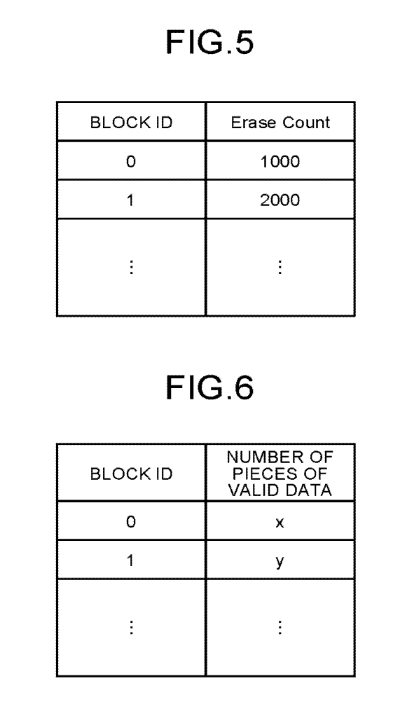

FIG. 5 is a diagram that illustrates a degree of wear management table managing the degree of wear of blocks. The degree of wear management table is included in the management information 32. In the case illustrated in FIG. 5, in order to manage the degree of wear of each block, an erase count is used. In the degree of wear management table, a relation between the block ID of each block and an erase count thereof is managed. In order to manage the degree of wear of each block, the number of times of rewriting for each block may be used, or further another parameter may be used. In a case where the erase count is used for managing the degree of wear of each block, the degree of wear management table and the block management table may be used together.

The ECC unit 23 executes an error correction coding process for data transmitted from the data buffer 31, thereby generating a parity. The ECC unit 23 outputs a code word including data and a parity to the memory I/F 40. The memory I/F 40 inputs the code word read from the NAND 10 to the ECC unit 23. The ECC unit 23 executes an error correction decoding process by using the input code word and transmits decoded data to the data buffer 31.

The GC control unit 25 controls garbage collection (compaction). In the memory system 100, in a case where a data erase unit (block) and a data read/write unit are different from each other, when the rewriting process for the NAND 10 proceeds, a block is fragmented due to invalid data. When the number of such fragmented blocks increases, the number of usable blocks decreases. Thus, for example, in a case where the number of free blocks of the NAND 10 is less than a certain threshold, the garbage collection (compaction) is executed, whereby the number of free blocks is increased. In the garbage collection, from blocks (GC source blocks) in which valid data and invalid data are included, the valid data is collected and is rewritten into blocks (GC destination blocks) of which data has been newly erased.

The temperature control unit 24 acquires the temperature information TC acquired by the temperature sensor 15 of each chip cp of the NAND 10 through the memory I/F 40. The temperature control unit 24 perceives a temperature state of each chip cp based on the temperature information TC of each chip. The temperature information TC of each chip cp may be spontaneously output from each chip cp to the memory controller 2 or may be output from each chip cp to the memory controller 2 in response to a request from the memory controller 2. In the latter case, a command used for acquiring the temperature information TC is transmitted from the memory controller 2 to each chip cp, and each chip cp transmits the temperature information TC to the memory controller 2 as a response to the command. In a case where the temperature of each chip is out of a certain range, in other words, when the temperature of each chip is over an upper limit or a lower limit, the temperature control unit 24 notifies the command processing unit 21 and the block management unit 22 of an occurrence of a temperature abnormality and a chip ID of the chip of which the temperature is abnormal. Here, the upper limit and the lower limit used for determining a temperature abnormality may be set to be different for each chip. Based on such a notification, the command processing unit 21 and the block management unit 22 can perceive an occurrence of a temperature abnormality and a chip ID of a chip of which the temperature is abnormal.

When the temperature of the inside of the chip is out of the certain range, there is a possibility that a block of a target for writing write data is a block disposed inside the saving area 10g. The temperature control unit 24 manages the saving blocks disposed inside the saving area 10g in cooperation with the block management unit 22. FIG. 6 is a diagram that illustrates a saving block management table. The saving block management table is included in the management information 32. In the saving block management table, a relation between the block ID of each saving block and the number of pieces of valid data in the block is managed.

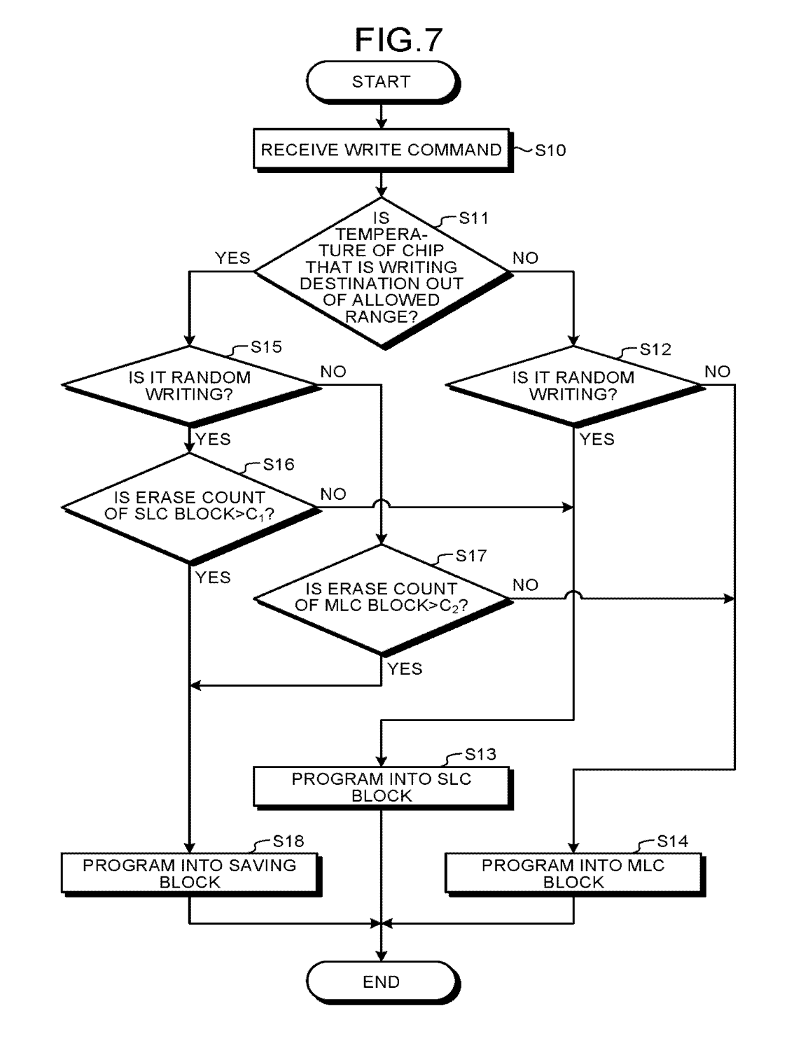

FIG. 7 is a flowchart that illustrates an example of the operation sequence of the memory system at the time of receiving a write command. When a write command is received from the host 1 (Step S10), the command processing unit 21 selects a memory chip of the NAND 10 into which write data is written. In addition, the command processing unit 21 determines whether or not the temperature of the memory chip that is a writing destination is out of a certain range based on the information transmitted from the temperature control unit 24 (Step S11).

In a case where the temperature of the memory chip that is the writing destination is within a certain range (Step S11: No), the command processing unit 21 executes a normal write sequence. For example, the command processing unit 21 determines whether or not a write request of this time is random write or sequential write based on the continuity of logical addresses specified by the write command (Step S12). In a case where the random write is determined (Step S12: Yes), the command processing unit 21 sets the writing destination of data to the SLC area 10s. In other words, the command processing unit 21 executes control of the ECC unit 23 and the memory I/F 40 such that an SLC block into which data is to be written from the SLC area 10s of the selected memory chip is selected, and the data specified by the write command and a parity are written into the selected SLC block.

Accordingly, a code word corresponding to the data specified by the write command is programmed into the SLC block of the SLC area 10s (Step S13). According to this data writing, the logical/physical translation table and the block management table are updated.

In a case where the sequential write is determined (Step S12: No), the command processing unit 21 sets the writing destination of the data to the MLC area 10m. In other words, the command processing unit 21 executes control of the ECC unit 23 and the memory I/F 40 such that an MLC block into which data is to be written from the MLC area 10m of the selected memory chip is selected, and the data specified by the write command and a parity are written into the selected MLC block. Accordingly, a code word corresponding to the data specified by the write command is programmed into the MLC block (Step S14). According to this data writing, the logical/physical translation table and the block management table are updated.

In a case where the temperature of the memory chip that is the writing destination is out of a certain range (Step S11: Yes), the command processing unit 21 determines whether or not a write request of this time is random write or sequential write based on the continuity of logical addresses specified by the write command, as described above (Step S15). In a case where the random write is determined (Step S15: Yes), the command processing unit 21 selects an SLC block into which data is to be written from the SLC area 10s of the selected memory chip. The command processing unit 21 determines a degree of wear of the selected SLC block based on the degree of wear management table illustrated in FIG. 5 described above. The command processing unit 21 acquires an erase count corresponding to the selected SLC block from the degree of wear management table and compares the acquired erase count with a threshold C1 (Step S16). In a case where the acquired erase count is the threshold C1 or less (Step S16: No), the command processing unit 21 executes control of the ECC unit 23 and the memory I/F 40 such that a code word corresponding to the data specified by the write command is written into the selected SLC block. Accordingly, the code word corresponding to the data specified by the write command is programmed into the SLC block of the SLC area 10s (Step S13). According to this data writing, the physical/logical translation table and the block management table are updated.

In a case where the acquired erase count is more than the threshold C1 (Step S16: Yes), the command processing unit 21 sets the writing destination of the data to the saving area 10g. In other words, the command processing unit 21 executes control of the ECC unit 23 and the memory I/F 40 such that a saving block into which data is to be written is selected from the saving area 10g of the selected memory chip, and the data specified by the write command and a parity are written into the selected saving block. Accordingly, a code word corresponding to the data specified by the write command is programmed into the saving block of the saving area 10g (Step S18). According to this data writing, the logical/physical translation table, the block management table, and the saving block management table illustrated in FIG. 6 are updated.

In a case where the sequential write is determined (Step S15: No) as a result of the determination made in Step S15, the command processing unit 21 selects an MLC block as a candidate for a data writing destination from the MLC area 10m of the selected memory chip. The command processing unit 21 determines a degree of wear of the selected MLC block based on the degree of wear management table illustrated in FIG. 5 described above. The command processing unit 21 acquires an erase count corresponding to the selected MLC block from the degree of wear management table and compares the acquired erase count with a threshold C2 (Step S17). In a case where the acquired erase count is the threshold C2 or less (Step S17: No), the command processing unit 21 executes control of the ECC unit 23 and the memory I/F 40 such that data specified by the write command and a parity are written into the selected MLC block. Accordingly, a code word corresponding to the data specified by the write command is programmed into the MLC block (Step S14). According to this data writing, the physical/logical translation table and the block management table are updated.

In a case where the acquired erase count is more than the threshold C2 (Step S17: Yes), the command processing unit 21 sets the writing destination of the data to the saving area 10g. In other words, the command processing unit 21 executes control of the ECC unit 23 and the memory I/F 40 such that an SLC block into which data is to be written is selected from the saving area 10g of the selected memory chip, and the data specified by the write command and a parity are written into the selected SLC block. Accordingly, a code word corresponding to the data specified by the write command is programmed into the SLC block of the saving area 10g (Step S18). According to this data writing, the logical/physical translation table, the block management table, and the saving block management table illustrated in FIG. 6 are updated.

In the embodiment described above, while the writing block has been switched based on whether the write request is either the random write or the sequential write, such a control process may not be executed. In such a case, in a case where a temperature abnormality occurs, a degree of wear of a block of the writing destination of data specified by the write command is determined. Then, in a case where the degree of wear is more than a threshold, the data is written into a saving block (SLC block) of the saving area 10g. On the other hand, in a case where the degree of wear is less than the threshold, the data is written into the block of the writing destination.

Here, the thresholds C1 and C2 may be set to be different for each chip.

In this way, in the embodiment, in a case where a temperature abnormality occurs, a degree of wear of a block of the writing destination of data specified by a write command is determined. Then, in a case where the degree of wear is larger than the threshold, the data is written into an SLC block of the saving area 10g that is especially prepared as a writing destination at the time of a temperature abnormality. The SLC block of the saving area 10g is used only when a temperature abnormality occurs. For this reason, the SLC block of the saving area 10g has a degree of wear smaller than the block of the SLC area 10s or the MLC area 10m and has reliability higher than the block of the SLC area 10s or the MLC area 10m. For this reason, also under an abnormal temperature environment, data maintaining characteristic having high reliability can be acquired.

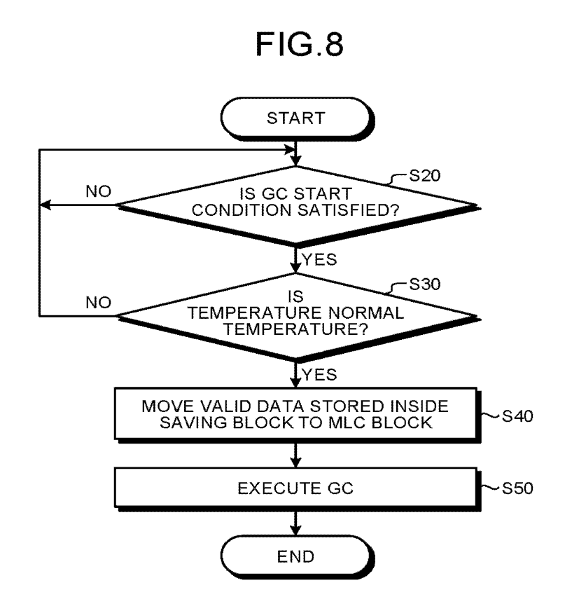

Next, moving of data stored in the saving area 10g will be described. Since the data stored in the saving area 10g is programmed under an abnormal temperature environment, the data stored in the saving area 10g is moved to a normal storage area at appropriate timing, and the data programmed in the abnormal temperature environment is protected. In this embodiment, the data stored in the saving area 10g is moved to the MLC area 10m. FIG. 8 is a flowchart that illustrates an example thereof. In the case illustrated in FIG. 8, when garbage collection is executed, data is moved from the saving area 10g. Further, the data stored in the saving area 10g may be moved to the SLC area 10s.

When a garbage collection start condition is satisfied (Step S20), the GC control unit 25 notifies the satisfaction of the garbage collection start condition to the temperature control unit 24. The temperature control unit 24 perceives a temperature state of each chip cp based on the temperature information TC acquired from each chip and determines whether the temperature of each chip is within a certain range (normal temperature) (Step S30). In a case where the temperature of each chip is within the certain range, the temperature control unit 24 recognizes the number of pieces of valid data stored in the saving block of each chip based on the saving block management table illustrated in FIG. 6. Then, the temperature control unit 24 reads all the valid data (valid code words) stored in the saving block of the saving area 10g of a certain chip and writes the read data into an MLC block of the MLC area of the same chip (Step S40). At the time of execution of this process, a decoding process and a coding process are executed by the ECC unit 23. The temperature control unit 24 executes such data moving for all the chips. According to the data moving, the logical/physical translation table, the block management table, and the saving block management table illustrated in FIG. 6 are updated. The temperature control unit 24 notifies the end of the data moving to the GC control unit 25. When such a notification is received, the GC control unit 25 executes garbage collection (Step S50).

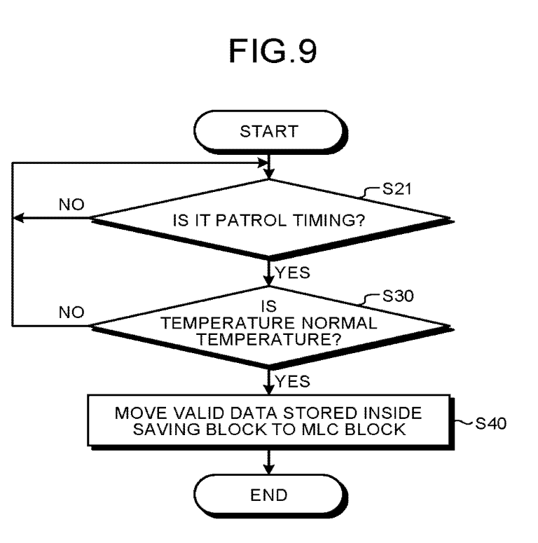

FIG. 9 illustrates an example of the operation for periodically executing the moving of data from the saving area 10g. A cycle time Tk used for periodically executing the moving of data is set in the temperature control unit 24. When the count value of a timer represents patrol timing matching the cycle time Tk (Step S21), the temperature control unit 24, as described above, determines whether the temperature of each chip is within a certain range (normal temperature) (Step S30). In a case where the temperature of each chip is within the certain range, the temperature control unit 24, as described above, moves all the valid data stored in the saving block of the saving area 10g to the MLC block of the MLC area of the same chip (Step S40). Such data moving is executed for all the chips.

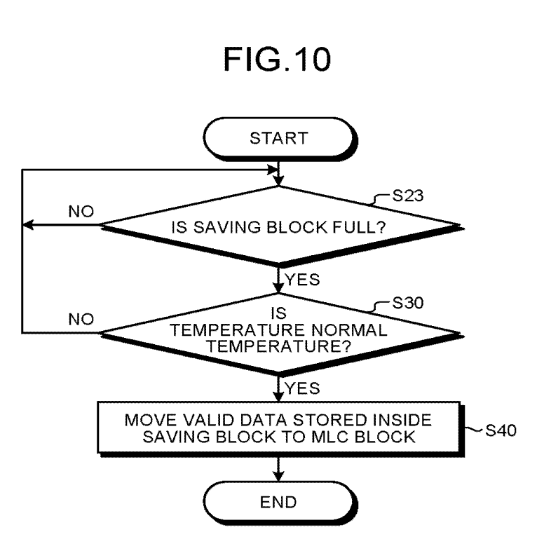

FIG. 10 illustrates an example of the operation for moving data from a saving block when the saving block is full of data. When it is detected that the saving block is full of data based on the saving block management table illustrated in FIG. 6 (Step S23), the temperature control unit 24, as described above, determines whether the temperature of the chip having the full saving block is within a certain range (normal temperature) (Step S30). In a case where the temperature of the chip is within the certain range, the temperature control unit 24, as described above, moves all the valid data stored in the saving block of the saving area 10g to the MLC block of the MLC area of the same chip (Step S40).

In a case where the saving area 10g includes a plurality of saving blocks, the data moving may be executed when one or a plurality of saving blocks are full of data, or the data moving may be executed when all the saving blocks are full of data.

In addition, in the examples illustrated in FIGS. 8 to 10, while the data moving is executed within the same chip, the data moving may be executed between chips different from each other. In addition, after storing data into the saving block, at a time point when the temperature of the chip is within an allowed temperature, immediately, the moving data from the saving block may be executed. Furthermore, after detecting that the temperature of each chip is within the allowed temperature, data may be moved from the saving block at a time point when the memory controller 2 is in an idle state.

In this way, in the embodiment, data written into the saving area 10g under an abnormal temperature environment is moved to the MLC area 10m, and accordingly, data programmed under an abnormal temperature environment can be protected.

### Second Embodiment

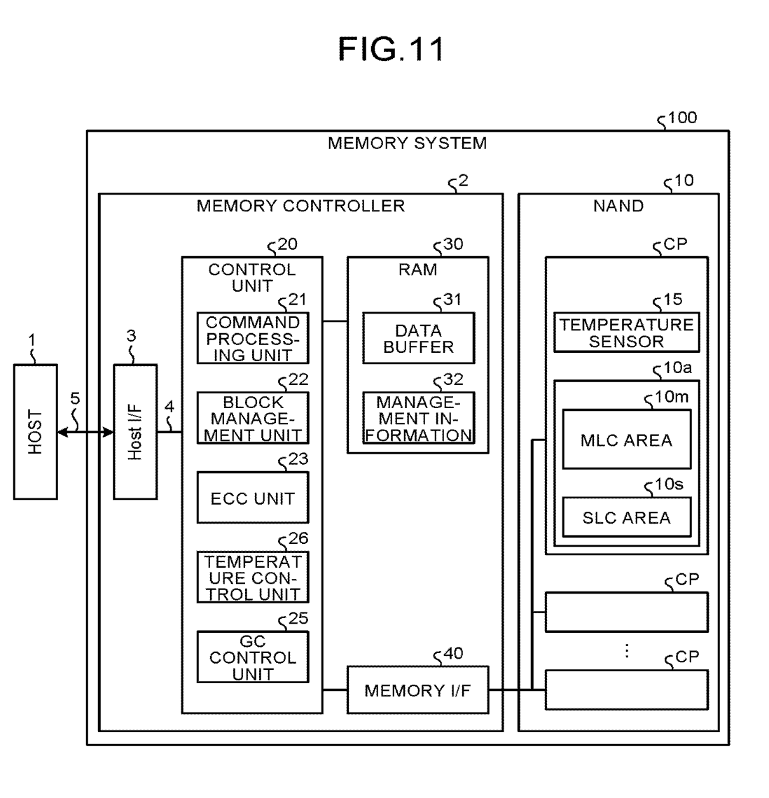

A second embodiment will be described with reference to FIGS. 11 to 14. In the second embodiment, a memory controller 2 determines each chip state based on the temperature of each memory chip and the degree of wear of each chip and corrects and sets a temperature coefficient that is set in each memory chip based on the determination.

FIG. 11 is a block diagram that illustrates an example of the configuration of a memory system 100 according to a second embodiment. While each memory chip cp of a NAND 10 includes an MLC area 10m and an SLC area 10s, any saving area 10g is not present therein. In addition, the function of a temperature control unit 26 of a control unit 20 of a memory controller 2 is different from that of the temperature control unit 24 according to the first embodiment. The same reference numeral is assigned to each constituent element achieving the same function as that of the memory system 100 illustrated in FIG. 1, and duplicate description will not be presented.

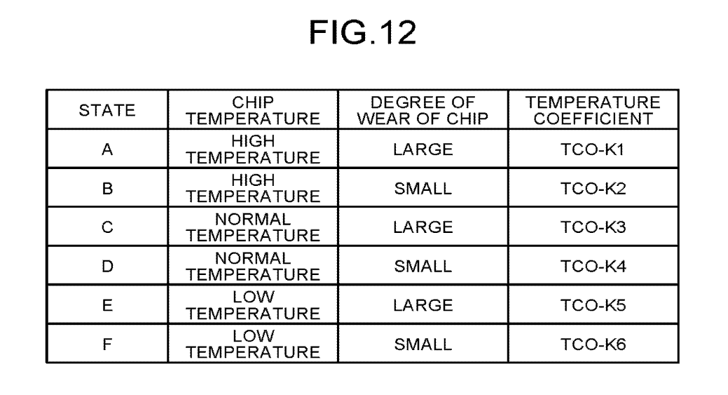

FIG. 12 is a diagram that illustrates a temperature coefficient management table managed by the temperature control unit 26. This temperature coefficient management table is included in management information 32 that is managed by the memory controller 2. In the temperature coefficient management table, a memory chip state is grouped into a plurality of mutually-different states A to F based on the temperature state of the memory chip and the degree of wear of the memory chip. A state A corresponds to a state in which the chip temperature is high, and the degree of wear of the chip is large. A state B corresponds to a state in which the chip temperature is high, and the degree of wear of the chip is small. A state C corresponds to a state in which the chip temperature is normal, and the degree of wear of the chip is large. A state D corresponds to a state in which the chip temperature is normal, and the degree of wear of the chip is small. A state E corresponds to a state in which the chip temperature is low, and the degree of wear of the chip is large. A state F corresponds to a state in which the chip temperature is low, and the degree of wear of the chip is small. A state in which the chip temperature is high represents a state in which the chip temperature is a threshold T1 or more. A state in which the chip temperature is normal represents a state in which the chip temperature is less than the threshold T1 and is a threshold T2 (here, T1>T2) or more. A state in which the chip temperature is low corresponds to a state in which the chip temperature is lower than the threshold T2. In addition, a state in which the degree of wear of a chip is large corresponds to a state in which a numerical value (for example, an average value of the number of times of erase of a block within the chip) representing the degree of wear of the chip is a threshold K or more. A state in which the degree of wear of a chip is small corresponds to a state in which a numerical value representing the degree of wear of the chip is less than the threshold K.

In the temperature coefficient management table, temperature coefficients TCO_K1 to TCO_K6 are set to the states A to F. In the example illustrated in FIG. 12, while the memory chips are grouped into six states A to F, the number of the groups may be decreased or increased.

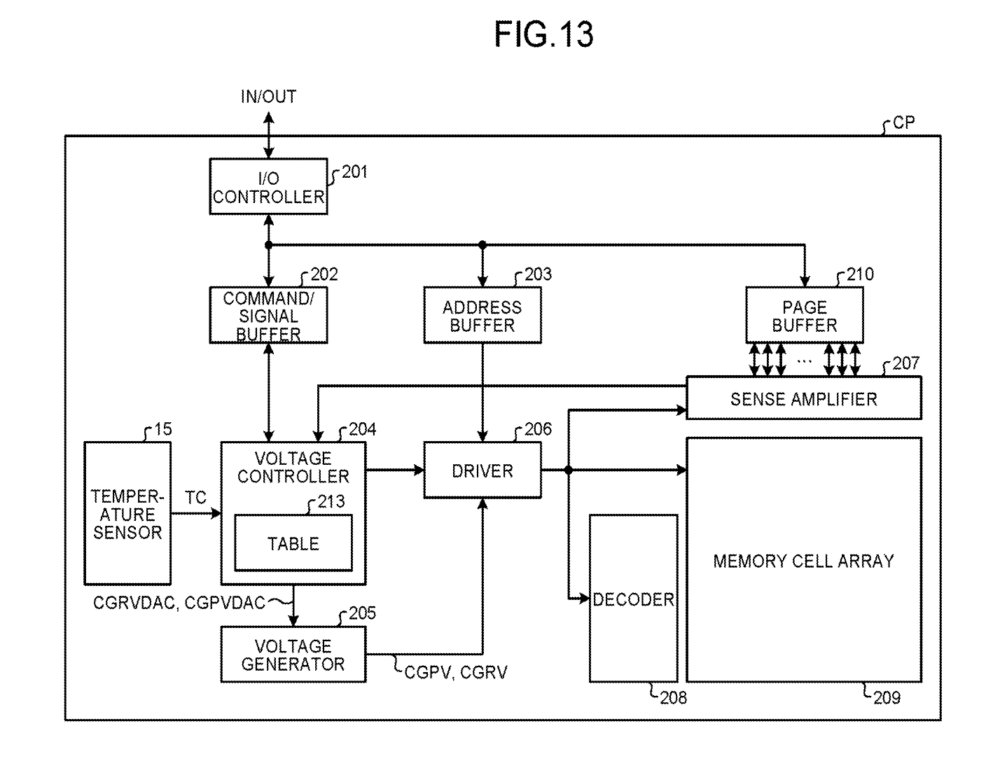

FIG. 13 is a diagram that illustrates an example of the internal configuration of each memory chip cp. The memory chip cp includes: an I/O (input/output) controller 201; a command/signal buffer 202; an address buffer 203; a voltage controller 204; a voltage generator 205; a driver 206; a sense amplifier 207; a decoder 208; a memory cell array 209; a page buffer 210; and a temperature sensor 15.

The I/O controller 201, based on an input signal IN, outputs a command transmitted from the memory controller 2 to the command/signal buffer 202 and outputs an address to the address buffer 203. In addition, the I/O controller 201 transmits data to the page buffer 210 at the time of writing the data and receives data from the page buffer 210 at the time of reading the data.

The command/signal buffer 202 decodes a command and outputs an instruction used for realizing an operation (for example, a read operation, a write operation, an erasing operation, or the like) represented by the command to the voltage controller 204. The address buffer 203 decodes an address and outputs the address the driver 206.

The voltage controller 204 controls an access operation for accessing the memory cell array 209 according to an instruction of the command transmitted from the command buffer 202.

The voltage generator 205, for example, generates a program voltage CGPV used for realizing a program operation based on a control signal CGPVDAC transmitted from the voltage controller 204. The voltage generator 205, for example, generates a read voltage CGRV used for realizing a reading operation based on a control signal CGRVDAC transmitted from the voltage controller 204. The driver 206 controls the operations of the sense amplifier 207, the decoder 208, and the memory cell array 209 based on an address transmitted from the address buffer 203 and an instruction transmitted from the voltage controller 204.

The temperature sensor 15 senses the temperature of the memory chip cp and outputs temperature information TC to the voltage controller 204. The temperature information TC is input to the memory controller 2 through the I/O controller 201.

The voltage controller 204 includes a table 213 in which a temperature coefficient and other parameter values are registered. The temperature coefficient registered in the table 213 can be changed using a command supplied from the memory controller 2. The temperature coefficient registered in the table 213 of each memory chip cp, for example, is the temperature coefficient TCO_K4 set in correspondence with the state D (the chip temperature is a normal temperature, and the degree of wear of the chip is small) registered in the temperature coefficient management table illustrated in FIG. 12.

At the time of programming, the voltage controller 204 acquires a temperature coefficient from the table 213, corrects a control signal CGPVDAC used for generating a program voltage by using the acquired temperature coefficient, and outputs the corrected control signal CGPVDAC. In addition, at the time of reading data, the voltage controller 204 acquires a temperature coefficient from the table 213, corrects a control signal CGRVDAC used for generating a read voltage by using the acquired temperature coefficient, and outputs the corrected control signal CGRVDAC.

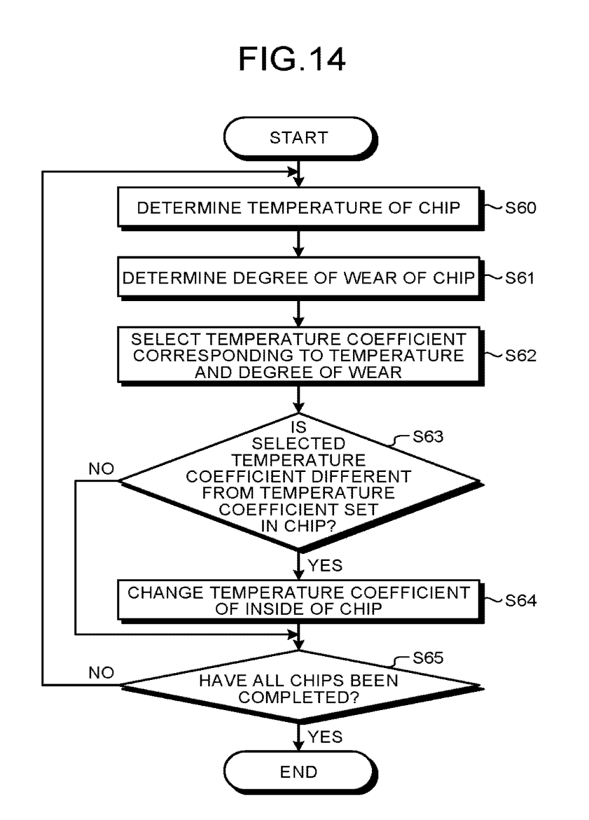

FIG. 14 is a flowchart that illustrates a setting changing process of a temperature coefficient that is executed by the temperature control unit 26 of the control unit 20. The temperature control unit 26, based on the temperature information TC transmitted from the temperature sensor 15 of a certain memory chip cp, determines whether the temperature of the memory chip cp is high, normal, or low (Step S60).

In addition, the temperature control unit 26 determines whether the degree of wear of the memory chip cp is large or small (Step S61). The degree of wear of the memory chip is calculated by using the number of times of erase of one or a plurality of blocks disposed inside the memory chip. For example, in order to calculate the degree of wear of the memory chip, the numbers of times of erase of all the blocks included in the memory chip may be acquired. In addition, the degree of wear of the memory chip may be calculated based on the number of times of erase of one or a plurality of certain blocks selected in advance as sampling targets. For example, the numbers of times of erase of a plurality of blocks that are sampling targets are acquired, and an average value or a maximum value thereof is set as the degree of wear of the memory chip.

The temperature control unit 26 determine one of the states A to F to which the memory chip belongs based on the temperature and the degree of wear that have been determined and acquires a temperature coefficient corresponding to the determined state from the temperature coefficient management table illustrated in FIG. 12 (Step S62). The temperature control unit 26 constantly stores the temperature coefficient that is currently registered in the table 213 arranged inside each memory chip cp. For example, at the time of the first operation of the memory system 100, the memory controller 2 transmits a command used for acquiring a current temperature coefficient to each memory chip cp. In response to this command, each memory chip cp transmits a current temperature coefficient to the memory controller 2. The memory controller 2 stores the received temperature coefficient of each memory chip cp as management information 32. In addition, whenever the temperature coefficient of each memory chip cp is updated, the memory controller 2 stores an updated temperature coefficient as the current temperature coefficient. The temperature control unit 26 determines whether or not the temperature coefficient acquired from the temperature coefficient management table is different from the temperature coefficient that is currently set in the memory chip (Step S63). In a case where both the temperatures are determined to be different from each other, the temperature control unit 26 changes the temperature coefficient stored inside the memory chip (Step S64). In other words, the temperature control unit 26 inputs an instruction including a command used for changing the temperature coefficient, a chip address, and a temperature coefficient for update to the memory chip through the memory I/F 40. The voltage controller 204 of the memory chip that has received this command updates the temperature coefficient stored inside the table 213 with the temperature coefficient included in the instruction. In a case where the determination made in Step S63 is No, the temperature control unit 26 does not execute the process of changing the temperature coefficient stored inside the memory chip. Such a process is executed for all the memory chips (Steps S65 to S64).

In this way, in the second embodiment, the temperature coefficient set inside the memory chip is changed based on the temperature inside of the memory chip and the degree of wear of the memory chip. For this reason, a data maintaining characteristic having high reliability can be acquired by controlling the program voltage or the reading voltage inside the NAND 10 based on the temperature and the degree of wear.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory system comprising:
a nonvolatile memory that includes a plurality of blocks, the plurality of blocks including a plurality of first blocks and at least one second block, the second block being different from the first block, the second block including a plurality of memory cells that stores data of one bit; and
a controller configured to:
in a case where a first temperature that is a temperature of the nonvolatile memory is within a certain range, write first data designated by a write request from a host into a third block, the third block being a block selected from among the first blocks;
in a case where the first temperature is out of the certain range and a first value of the third block is more than a threshold, write the first data into the second block, the first value being a degree of wear; and
in a case where the first temperature is out of the certain range and the first value of the third block is less than the threshold, write the first data into the third block.

2. The memory system according to claim 1,
wherein the first blocks includes fourth blocks and fifth blocks, the fourth block including a plurality of memory cells that stores data of one bit, the fifth blocks including a plurality of memory cells that stores data of two or more bits, and
wherein the controller selects the third block from among the fourth blocks and the fifth blocks.

3. The memory system according to claim 2, wherein the controller is configured to
write the first data into the fifth block in a case where addresses specified by the write request is determined to be continuous, and
write the first data into the fourth block in a case where the addresses specified by the write request is determined not to be continuous.

4. The memory system according to claim 1,
wherein the nonvolatile memory includes a first memory chip that includes the first blocks and the second block, and
wherein the controller writes the first data into the second block disposed in the first memory chip in a case where the first value of the third block disposed in the first memory chip is more than the threshold.

5. The memory system according to claim 1,
wherein the first value of the second block is more than the first value of the first block.

6. The memory system according to claim 1, wherein,
in a case where the first temperature is within the certain range after the first data is written into the second block, the controller executes a first processing, the first processing including reading the first data from the second block and writing the read first data into a sixth block among the first blocks.

7. The memory system according to claim 2, wherein,
in a case where the first temperature is within the certain range after the first data is written into the second block, the controller executes a second processing, the second processing including reading the first data from the second block and writing the read first data into the fifth block.

8. The memory system according to claim 6,
wherein the controller, after executing the first processing, reads valid data stored in a seventh block among the first blocks and writes the read valid data into an eight block among the first blocks.

9. The memory system according to claim 6, wherein the controller periodically executes the first processing.

10. A method of controlling a nonvolatile memory including a plurality of blocks, the plurality of blocks including a plurality of first blocks and at least one second block, the second block being different from the first block, the second block including a plurality of memory cells that stores data of one bit, the method comprising:
in a case where a first temperature that is a temperature of the nonvolatile memory is within a certain range, writing first data requested to be written from a host into a third block, the third block being a block selected from among the first blocks;
in a case where the first temperature is out of the certain range and a first value of the third block is more than a threshold, writing the first data into the second block, the first value being a degree of wear; and
in a case where the first temperature is out of the certain range and the first value of the third block is less than the threshold, writing the first data into the third block.

11. The method according to claim 10,
wherein the first blocks includes fourth blocks and fifth blocks, the fourth block including a plurality of memory cells that stores data of one bit, the fifth blocks including a plurality of memory cells that stores data of two or more bits,
the method further comprising selecting the third block from among the fourth blocks and the fifth blocks.

12. The method according to claim 11, further comprising:
writing the first data into the fifth block in a case where addresses specified by the write request is determined to be continuous, and
writing the first data into the fourth block in a case where the addresses specified by the write request is determined not to be continuous.

13. The method according to claim 10, wherein the nonvolatile memory includes a first memory chip that includes the first blocks and the second block,
the method further comprising writing the first data into the second block disposed in the first memory chip in a case where the first value of the third block disposed in the first memory chip is more than the threshold.

14. The method according to claim 10, wherein the first value of the second block is more than the first value of the first block.

15. The method according to claim 10, further comprising
in a case where the first temperature is within the certain range after the first data is written into the second block, executing a first processing, the first processing including reading the first data from the second block and writing the read first data into a sixth block among the first blocks.

16. The method according to claim 11, further comprising
in a case where the first temperature is within the certain range after the first data is written into the second block, executing a second processing, the second processing including reading the first data from the second block and writing the read first data into the fifth block.

17. A memory system comprising:
a nonvolatile memory that includes a memory cell array including a plurality of memory cells and a control unit;
a controller configured to:
group a state of the nonvolatile memory into a plurality of states based on a temperature of the nonvolatile memory and a degree of wear of the nonvolatile memory;
transmit a command designating a temperature coefficient corresponding to a first state to the nonvolatile memory in a case where the nonvolatile memory is in the first state among the plurality of states; and
transmit a command designating a temperature coefficient corresponding to a second state to the nonvolatile memory in a case where the nonvolatile memory is in the second state among the plurality of states.

18. The memory system according to claim 17, wherein the control unit of the nonvolatile memory updates a temperature coefficient stored in a memory of the control unit with the temperature coefficient designated in the command received from the controller.

19. The memory system according to claim 18, wherein the control unit of the nonvolatile memory determines a program voltage or a reading voltage applied to the memory cells based on the temperature coefficient stored in the memory of the control unit.

20. The memory system according to claim 17,
wherein the nonvolatile memory includes first and second memory chips, the first memory chip including a first memory cell array including a plurality of first memory cells and a first control unit, the second memory chip including a second memory cell array including a plurality of second memory cells and a second control unit, and
wherein the controller is configured to:
group a state of the first memory chip into a plurality of states based on a temperature of the first memory chip and a degree of wear of the first memory chip;
group a state of the second memory chip into a plurality of states based on a temperature of the second memory chip and a degree of wear of the second memory chip;
transmit a command designating a temperature coefficient corresponding to a first state to the first memory chip in a case where the first memory chip is in the first state among the plurality of states;
transmit a command designating a temperature coefficient corresponding to a first state to the second memory chip in a case where the second memory chip is in the first state among the plurality of states;
transmit a command designating a temperature coefficient corresponding to a second state to the first memory chip in a case where the first memory chip is in the second state among the plurality of states; and
transmit a command designating a temperature coefficient corresponding to a second state to the second memory chip in a case where the second memory chip is in the second state among the plurality of states.
